(19) United States
(12) Patent Application Publication
(10) Pub. No.: US 2025/0267204 A1
(43) Pub. Date: Aug. 21, 2025

(54) CASE INCLUDING SHIELDING MEMBER AND ELECTRONIC DEVICE MOUNTED THEREON

(71) Applicant: SAMSUNG ELECTRONICS CO., LTD., Suwon-si (KR)

(72) Inventors: Mincheol HA, Suwon-si (KR); Dongzo KIM, Suwon-si (KR)

(73) Assignee: SAMSUNG ELECTRONICS CO., LTD., Suwon-si (KR)

(21) Appl. No.: 19/201,556

(22) Filed: May 7, 2025

Related U.S. Application Data
(63) Continuation of application No. PCT/KR2023/017687, filed on Nov. 6, 2023.

(30) Foreign Application Priority Data
Nov. 7, 2022 (KR) 10-2022-0146824
Nov. 25, 2022 (KR) 10-2022-0160633

(51) Int. Cl. H04M 1/02; H01F 27/28; H02J 50/10; H02J 50/70

(52) U.S. Cl. CPC H04M 1/0203; H01F 27/28; H02J 50/70; H02J 50/10

(57) ABSTRACT

Provided is a case of an electronic device including a case body, a card storage on a surface of the case body, the card storage including a storage space configured to store a card, and a shielding member in the storage space, wherein at least a portion of the shielding member is configured to change in shape or position to be between the card and a coil of the electronic device based on the card being stored in the storage space.

### CROSS-REFERENCE TO RELATED APPLICATIONS

This application is a bypass continuation of International Application No. PCT/KR2023/017687, filed on Nov. 6, 2023, which is based on and claims priority to Korean Patent Application No. 10-2022-0146824, filed on Nov. 7, 2022 and Korean Patent Application No. 10-2022-0160633, filed on Nov. 25, 2022, in the Korean Intellectual Property Office, the disclosures of which are incorporated by reference herein in their entireties.

### BACKGROUND

### 1. Field

Embodiments of the present disclosure relate to a case including a shielding member and an electronic device mounted on the case.

### 2. Description of Related Art

Wireless charging is a technology for charging the battery of an electronic device (e.g., a mobile phone) without connecting a separate charging connector to it, using wireless power transmission and reception.

A wireless power transmission device may transmit power to a wireless power reception device by at least one of inductive coupling based on an electromagnetic induction phenomenon caused by a wireless power signal or electromagnetic resonance coupling based on an electromagnetic resonance phenomenon caused by a wireless power signal of a specific frequency.

An electronic device that supports wireless charging power reception may receive power from an external device through an antenna and charge a battery with the received power. An electronic device that supports wireless charging power transmission may supply wireless power to another electronic device using the power of a battery or power received from a connected wired charger. For example, a wireless charging power transmission device may generate designated power using power from an external device (e.g., a TA adapter) or power of a battery, and supply the generated power to another electronic device (e.g., a smartphone, a smart watch, or wireless earphones (e.g., true wireless stereo)) through a coil.

### SUMMARY

One or more embodiments provide a case including a shielding member and an electronic device mounted on the case.

According to an aspect of an embodiment, there is provided a case of an electronic device including a case body, a card storage on a surface of the case body, the card storage including a storage space configured to store a card, and a shielding member in the storage space, wherein at least a portion of the shielding member is configured to change in shape or position to be between the card and a coil of the electronic device based on the card being stored in the storage space.

The shielding member may include a shielding sheet configured to be on the coil of the electronic device based on the card being stored in the storage space, and configured not to be on the coil of the electronic device based on the card not being stored in the storage space.

The shielding sheet may include at least one of a non-metal material, a ferrite material, and a nano-crystal material.

The shielding sheet may be configured to block wireless power transmitted from an external wireless power transmission device from reaching the coil of the electronic device.

The shielding member may include a first region on at least a portion of the storage space, and a second region extending from the first region and configured to be on the coil of the electronic device or not to be on the coil of the electronic device.

The second region may be configured to be on the coil of the electronic device in a spread out shape from the first region or configured not to be on the coil of the electronic device in a rolled shape toward the first region.

The shielding member may include a shielding sheet, and an elastic sheet stacked on the shielding sheet, wherein the elastic sheet is configured to provide an elastic restoring force to change the second region into the rolled shape based on the card not being stored in the storage space.

The shielding member may include a shielding sheet, a rotation shaft on at least a portion of the storage space, and a connecting member, wherein a first end of the connecting member is connected to the rotation shaft and a second end of the connecting member is connected to the shielding sheet.

The shielding sheet may be configured to rotate in a first direction relative to the rotation shaft to be on the coil of the electronic device based on the card being stored in the storage space, and configured to rotate in a second direction relative to the rotation shaft to not be on the coil of the electronic device based on the card not being stored in the storage space.

The case may further include a support member configured to support the card based on the card being stored in the storage space.

According to an aspect of an embodiment, there is provided a case of an electronic device including a case body configured to mount the electronic device thereon, the case body including a flat portion and a side portion extending from an edge of the flat portion, a card storage on the flat portion of the case body, the card storage including a storage space configured to store a card, and a shielding member in the storage space, wherein at least a portion of the shielding member is configured to change in shape or position to be between the card and a coil of the electronic device based on the card being stored in the storage space.

The case body may further include a camera opening on at least a portion of the flat portion.

The shielding member may be configured to block wireless power transmitted from an external device from reaching the coil of the electronic device, based on the at least portion of the shielding member being between the card and the coil of the electronic device.

The shielding member may include a shielding sheet, and an elastic sheet on the shielding sheet, and the elastic sheet may be configured to provide an elastic restoring force to change the shielding sheet and the elastic sheet into a rolled shape based on the card not being stored in the storage space.

The shielding member may include a shielding sheet, a rotation shaft on at least a portion of the storage space, and a connecting member, wherein a first end of the connecting member may be connected to the rotation shaft and a second end of the connecting member is connected to the shielding sheet.

The shielding member may include a shielding sheet configured to be on the coil of the electronic device based on the card being stored in the storage space, and configured not to be on the coil of the electronic device based on the card not being stored in the storage space.

The shielding sheet may include at least one of a non-metal material, a ferrite material, and a nano-crystal material.

The shielding member may include a first region on at least a portion of the storage space, and a second region extending from the first region and configured to be on the coil of the electronic device or not to be on the coil of the electronic device.

The second region may be configured to be on the coil of the electronic device in a spread out shape from the first region or configured not to be on the coil of the electronic device in a rolled shape toward the first region.

The case may further include a support member configured to support the card based on the card being stored in the storage space.

### BRIEF DESCRIPTION OF DRAWINGS

Embodiments will be more clearly understood from the following detailed description taken in conjunction with the accompanying drawings in which:

FIG. 1 is a block diagram illustrating an electronic device in a network environment according to an embodiment;

FIG. 2 is a block diagram illustrating an electronic device and a wireless power transmission device according to an embodiment;

FIG. 3 is a block diagram illustrating a wireless power transmission device and an electronic device receiving wireless power according to an embodiment;

FIG. 4 is a perspective view illustrating an electronic device and a case of the electronic device, which are separated from each other according to an embodiment;

FIGS. 5A and 5B are cross-sectional views illustrating a case of an electronic device, the electronic device, and a wireless power transmission device according to an embodiment;

FIG. 6 is a cross-sectional view illustrating a shielding member according to an embodiment;

FIGS. 7A and 7B are plan views illustrating a shielding member of a case in an electronic device according to an embodiment;

FIG. 8 is a flowchart illustrating control of wireless charging of an electronic device according to an embodiment; and

FIG. 9 is a graph illustrating a rectified voltage of a rectifier circuit in an electronic device according to an embodiment.

### DETAILED DESCRIPTION

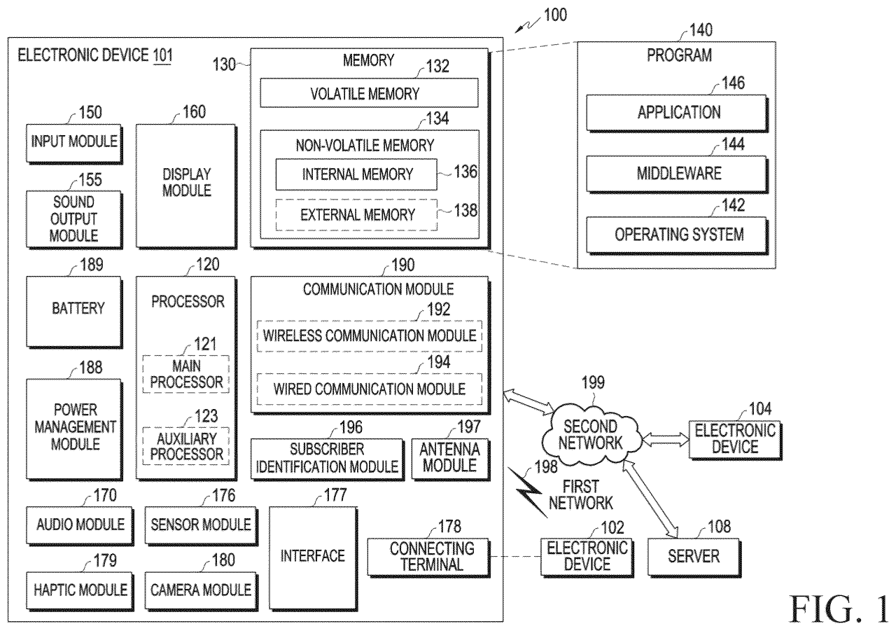

FIG. 1 is a block diagram illustrating an electronic device 101 in a network environment 100 according to an embodiment.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the strength of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to an embodiment may be one of various types of electronic devices. The electronic devices may include, for example, a portable communication device (e.g., a smartphone), a computer device, a portable multimedia device, a portable medical device, a camera, a wearable device, or a home appliance. According to an embodiment, the electronic devices are not limited to those described above.

It should be appreciated that an embodiment of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1st” and “2nd”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wiredly), wirelessly, or via a third element.

As used in connection with an embodiment of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

An embodiment as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store, or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities, and some of the multiple entities may be separately disposed in different components. According to an embodiment, one or more of the above-described components may be omitted, or one or more other components may be added. Alternatively or additionally, a plurality of components (e.g., modules or programs) may be integrated into a single component. In such a case, according to an embodiment, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

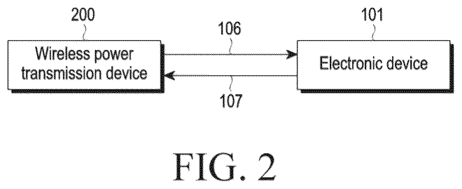

FIG. 2 is a block diagram illustrating an electronic device and a wireless power transmission device according to an embodiment.

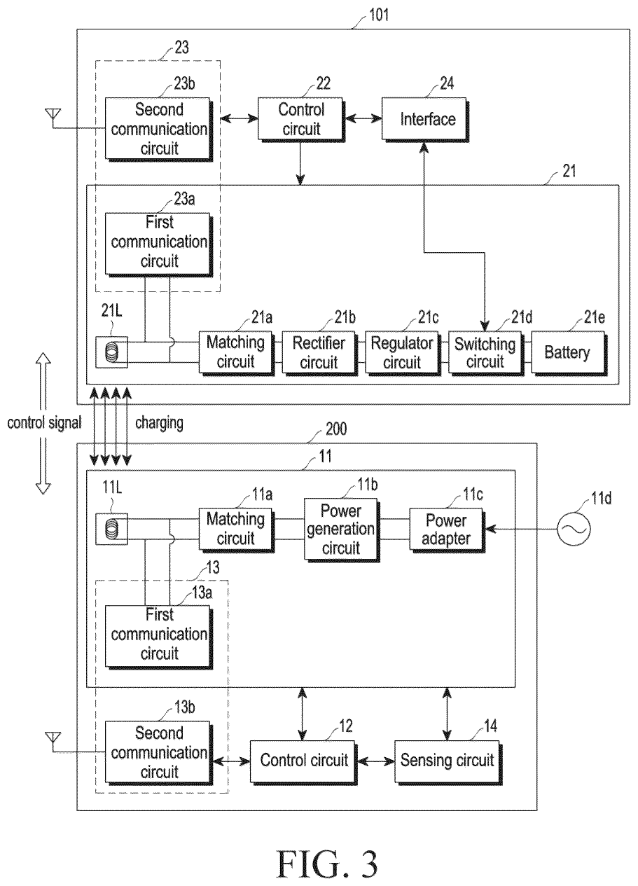

The embodiment of FIG. 2 may be combined with the embodiment of FIG. 1 or the embodiments of FIGS. 3 to 9.

The configuration of the electronic device 101 in FIG. 2 may be partially or wholly the same as the configuration of the electronic device 101 in FIG. 1.

According to an embodiment, a wireless power transmission device 200 may wirelessly transmit power 106 to the electronic device 101 (e.g., the electronic device 101 of FIG. 1). According to an embodiment, the electronic device 101 may be defined and/or referred to as a wireless power reception device.

According to an embodiment, the wireless power transmission device 200 may receive information 107 from the electronic device 101. In an example, the wireless power transmission device 200 may transmit the power 106 according to an inductive method. When the wireless power transmission device 200 operates according to the inductive method, the wireless power transmission device 200 may include, for example, at least one of a power source, a DC-DC conversion circuit (e.g., a DC/DC converter), a DC-AC conversion circuit (e.g., an inverter), an amplifier circuit, an impedance matching circuit, at least one capacitor, at least one coil, or a communication modulation circuit. For example, at least one capacitor may form a resonant circuit together with at least one coil. For example, the coil means an antenna for transmitting and/or receiving wireless power, and is not limited to an antenna formed in a coil shape. In an embodiment, the wireless power transmission device 200 may be implemented in a manner defined in the Qi standard of the wireless power consortium (WPC). The wireless power transmission device 200 may include a coil capable of generating an induced magnetic field, when current flows according to the inductive method. The process of generating an induced magnetic field by the wireless power transmission device 200 may be referred to wireless transmission of the power 106 by the wireless power transmission device 200. Further, an induced electromotive force (or current, voltage, and/or power) may be generated in a coil of the electronic device 101 by a magnetic field generated in the surroundings. The process of generating an induced electromotive force through the coil may be referred to as wireless reception of the power 106 by the electronic device 101.

The wireless power transmission device 200 according to an embodiment may perform communication with the electronic device 101. For example, the wireless power transmission device 200 may perform communication with the electronic device 101 according to an in-band method. The wireless power transmission device 200 may modulate data to be transmitted, for example, by frequency shift keying (FSK), and the electronic device 101 may provide the information 107 by modulating it in amplitude shift keying (ASK). The wireless power transmission device 200 may identify the information 107 provided by the electronic device 101 based on the amplitude of a current and/or voltage applied to the coil of the wireless power transmission device 200. Although FIG. 1 illustrates that the electronic device 101 directly transmits the information 107 to the wireless power transmission device 200, this is only for helping understanding, and those skilled in the art will understand that the electronic device 101 only controls on/off of at least one switch inside it. An operation of performing modulation based on ASK and/or FSK may be understood as an operation of transmitting data or a packet according to the in-band communication method, and an operation of performing demodulation based on ASK and/or FSK may be understood as an operation of receiving data or a packet according to the in-band communication method. Transmitting and receiving data according to the in-band communication method is merely exemplary, and those skilled in the art will understand that the wireless power transmission device 200 and the electronic device 101 may transmit and receive data based on an out-of-band method (e.g., Bluetooth low energy (BLE) or various short-range communication methods).

The wireless power transmission device 200 or the electronic device 101 performing a specific operation may indicate that various hardware included in the wireless power transmission device 200 or the electronic device 101, for example, a controller (e.g., a micro controlling unit (MCU), a field programmable gate array (FPGA), an application specific integrated circuit (ASIC), a microprocessor, or an application processor (AP)) performs the specific operation. As another example, the wireless power transmission device 200 or the electronic device 101 performing a specific operation may indicate that the controller controls other hardware to perform the specific operation. As yet another example, the wireless power transmission device 200 or the electronic device 101 performing a specific operation may indicate that at least one instruction for performing the specific operation stored in a storage circuit (e.g., memory) of the wireless power transmission device 200 or the electronic device 101 is executed, and thus causes the controller or other hardware to perform the specific operation.

FIG. 3 is a block diagram illustrating a wireless power transmission device and an electronic device receiving wireless power according to an embodiment.

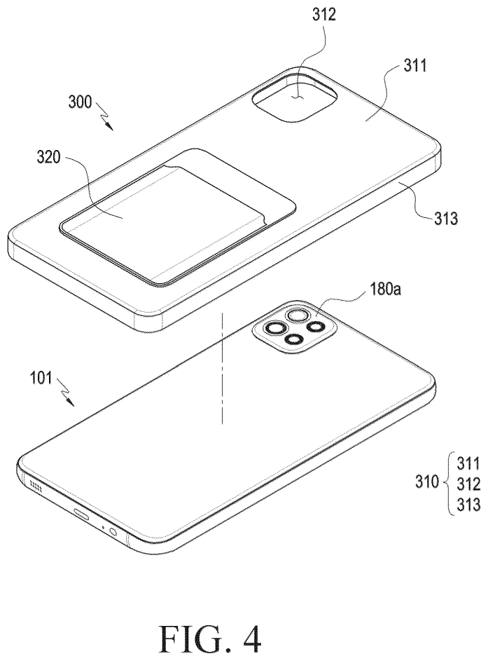

The embodiment of FIG. 3 may be combined with the embodiments of FIGS. 1 and 2 or the embodiments of FIGS. 4 to 9.

The configuration of the electronic device 101 in FIG. 3 may be partially or wholly the same as the configuration of the electronic device 101 in FIGS. 1 and 2. The configuration of the wireless power transmission device 200 in FIG. 3 may be partially or wholly the same as the configuration of the wireless power transmission device 200 in FIG. 2.

According to an embodiment, the wireless power transmission device 200 may include at least one of a power transmission circuit 11, a control circuit 12, a communication circuit 13, or a sensing circuit 14. The electronic device 101 that wirelessly receives power may include at least one of a power reception circuit 21, a control circuit 22, a communication circuit 23, or an interface 24.

According to an embodiment, the power transmission circuit 11 may provide power to the electronic device 101. For example, the power transmission circuit 11 may include a power adapter 11c, a power generation circuit 11b, a matching circuit 11a, a coil (or conductive pattern) 11L, or a first communication circuit 13a. The power transmission circuit 11 may be configured to wirelessly transmit power to the electronic device 101 through the coil 11L. The power transmission circuit 11 may receive power from the outside in the form of a DC or AC waveform and supply the received power to the electronic device 101 in the form of an AC waveform. For example, the coil 11L may include a plurality of coils and/or a coil wound with a plurality of turns.

The power adapter 11c may receive AC or DC power from the outside or a power signal from a built-in battery device and output it as DC power having a set voltage value. According to an embodiment, the power adapter 11c may be electrically connected to a power supply 11d located externally. For example, a cable of the power supply 11d may be directly connected to the power adapter 11c having a terminal. The voltage value of the DC power output from the power adapter 11c may be controlled by the control circuit 12. The DC power output from the power adapter 11c may be output to the power generation circuit 11b.

The power generation circuit 11b may convert a DC current output from the power adapter 11c into an AC current and output the AC current. For example, the power generation circuit 11b may include a predetermined amplifier. When a DC voltage or current input through the power adapter 11c is smaller than a set gain, it may be amplified to a set value using the amplifier. The power generation circuit 11b may include a circuit that converts the DC current received from the power adapter 11c into the AC current based on a control signal received from the control circuit 12. The power generation circuit 11b may include a bridge circuit including a plurality of switches. For example, the coil 11L may include a plurality of coils (or a coil wound with a plurality of turns), and the plurality of coils (or the coil wound with the plurality of turns) may share at least a portion of the power generation circuit 11b. This will be described in more detail later. For example, the power generation circuit 11b may convert the DC current into the AC current through a predetermined inverter. The power generation circuit 11b may include a gate driving device. The gate driving device may also change the DC current into the AC current, while controlling the DC current by turning it on/off. Alternatively, the power generation circuit 11b may generate an AC power signal through a wireless power generator (e.g., an oscillator).

The matching circuit 11a may perform impedance matching. For example, when the AC signal output from the power generation circuit 11b is transmitted to the coil 11L, an electromagnetic field may be formed in the coil 11L by the AC signal. In an embodiment, the AC signal may be provided only to some of the plurality of coils (or the coil wound with the plurality of turns), which will be described in more detail later. The frequency band of the formed electromagnetic field signal may be adjusted by adjusting the impedance of the matching circuit 11a. The matching circuit 11a may control output power transmitted to the electronic device 101 through the coil 11L to be highly efficient or high output by impedance adjustment. The matching circuit 11a may adjust impedance under the control of the control circuit 12. For example, the matching circuit 11a may include at least one of an inductor (e.g., a coil (or conductive pattern)), a capacitor, or a switching device. The control circuit 12 may control a connection state with at least one of the inductor or the capacitor through the switching device, and perform impedance matching accordingly. For example, at least one of the control circuit 12 or the control circuit 52 may be implemented as a variety of circuits capable of performing operations, such as a general-purpose processor like a CPU, a minicomputer, a microprocessor, an MCU, or an FPGA, and its type is not limited.

When current is applied to the coil 11L, the coil 11L may form a magnetic field for inducing or resonating current in the electronic device 101. In an embodiment, the first communication circuit 13a (e.g., resonant circuit) may perform communication (e.g., data communication) in an in-band manner using electromagnetic waves generated by the coil 11L.

The sensing circuit 14 may periodically or aperiodically measure a change in a current/voltage applied to the coil 11L of the power transmission circuit 11. The wireless power transmission device 200 may change the amount of power to be transmitted according to the change in the current/voltage applied to the coil 11L. For example, the sensing circuit 14 may periodically or aperiodically sense a temperature change of the wireless power transmission device 200. According to an embodiment, the sensing circuit 14 may include at least one of a current/voltage sensor or a temperature sensor.

The control circuit 12 may control to wirelessly transmit power to the electronic device 101 through the power transmission circuit 11. The control circuit 12 may control to wirelessly transmit or receive information to or from the electronic device 101 through the communication circuit 13. The control circuit 12 may calculate the amount of power received from the electronic device 101 based on a current or voltage measured by the sensing circuit 14.

According to an embodiment, the received information may include at least one of charging configuration information related to a battery state of the electronic device 101, power amount control information related to adjusting the amount of power transmitted to the electronic device 101, environmental information related to a charging environment of the electronic device 101, or time information about the electronic device 101.

The charging configuration information may be information related to the battery state of the electronic device 101 at a time of wireless charging between the wireless power transmission device 200 and the electronic device 101. For example, the charging configuration information may include at least one of a total battery capacity, battery remaining capacity, number of charges, battery usage, charging mode, charging method, or wireless reception frequency band of the electronic device 101.

For example, the power amount control information may be information for controlling the amount of the transmitted initial power according to a change in the amount of power charged in the electronic device 101 during wireless charging between the wireless power transmission device 200 and the electronic device 101.

The environmental information is information for measuring the charging environment of the electronic device 101 by the interface 24 of the electronic device 101, and may include, for example, at least one of temperature data including at least one of an internal temperature or external temperature of the electronic device 101, illuminance data indicating an ambient illuminance (brightness) of the electronic device 101, or sound data indicating ambient sound (noise) of the electronic device 101.

The control circuit 12 may be controlled to generate or transmit power to be transmitted to the electronic device 101 based on the charging configuration information out of the received information. For example, the control circuit 12 may determine or change the amount of power to be transmitted to the electronic device 101 based on at least a portion of the received information (e.g., at least one of the power amount control information, the environmental information, or the time information). For example, the control circuit 12 may control the matching circuit 11a to change impedance.

The communication circuit 13 may perform communication with the electronic device 101 in a predetermined method. The communication circuit 13 may perform data communication with the communication circuit 23 of the electronic device 101. For example, the communication circuit 13 may unicast, multicast, or broadcast a signal.

According to an embodiment, the communication circuit 13 may include at least one of the first communication circuit 13a implemented as one hardware with the power transmission circuit 11 so that the wireless power transmission device 200 may perform communication in an in-band manner or a second communication circuit 13b implemented as hardware different from the power transmission circuit 11 so that the wireless power transmission device 200 may perform communication in an out-of-band manner.

According to an embodiment, when the communication circuit 13 includes the first communication circuit 13a capable of performing communication in an in-band manner, the first communication circuit 13 may receive the frequency and signal level of an electromagnetic field signal received through the coil 11L of the power transmission circuit 11. The control circuit 12 may decode the frequency and signal level of the received electromagnetic field signal to extract information received from the electronic device 101. Alternatively, the first communication circuit 13 may apply a signal for information about the wireless power transmission device 200 to be transmitted to the electronic device 101 to the coil 11L of the power transmission circuit 11 or add the signal for the information about the wireless power transmission device 200 to an electromagnetic field signal generated by applying a signal output from the matching circuit 11a to the coil 11L, thereby transmitting the signal to the electronic device 101. The control circuit 12 may control the output by changing a connection state with at least one of the inductor or capacitor of the matching circuit 11a through on/off control of the switching device included in the matching circuit 11a.

According to an embodiment, when the communication circuit 13 includes the second communication circuit 13b capable of performing communication in an out-of-band manner, the second communication circuit 13b may perform communication with the communication circuit 23 of the electronic device 101 using a communication method such as near field communication (NFC), Zigbee communication, infrared communication, visible light communication, Bluetooth communication, or BLE.

The above communication methods of the communication circuit 13 are merely exemplary, and the embodiments of the disclosure are not limited in scope to a specific communication method performed by the communication circuit 13.

According to an embodiment, the electronic device 101 may include the power reception circuit 21, the control circuit 22, the communication circuit 23, or the interface 24. The power reception circuit 21 of the electronic device 101 may receive power from the power transmission circuit 11 of the wireless power transmitting device 200. In an embodiment, the power reception circuit 21 may be implemented in the form of a built-in battery or a power reception interface to receive power from the outside. For example, the power reception circuit 21 may include a matching circuit 21a, a rectifier circuit 21b, a regulator circuit 21c, a switching circuit 21d, a battery 21e, or a coil 21L.

The power reception circuit 21 may receive wireless power in the form of electromagnetic waves generated in response to a current/voltage applied to the coil 11L of the power transmission circuit 11 through the coil 21L. For example, the power reception circuit 21 may receive power using an electromotive force formed in the coil 11L of the power transmission circuit 11 and the coil 21L of the power reception circuit 21.

The matching circuit 21a may perform impedance matching. For example, power transmitted through the coil 11L of the wireless power transmission device 200 may be transferred to the coil 21L to form an electromagnetic field. The matching circuit 21a may adjust the frequency band of the formed electromagnetic field signal by adjusting impedance. The matching circuit 21a may control input power received from the wireless power transmission device 200 through the coil 21L to be highly efficient and high output by impedance adjustment. The matching circuit 21a may adjust impedance under the control of the control circuit 22. The matching circuit 21a may include, for example, at least one of an inductor (e.g., a coil (or conductive pattern)), a capacitor, or a switching device. The control circuit 22 may control a connection state with at least one of the inductor or the capacitor through the switching device, and perform impedance matching accordingly.

The rectifier circuit 21b may rectify wireless power received by the coil 21L into a DC current, and may be implemented in the form of a bridge diode, for example.

The regulator circuit 21c may convert the rectified power into a set voltage or current. The regulator circuit 21c may include a DC/DC converter. For example, the regulator circuit 21c may convert the rectified power so that the voltage of an output terminal becomes 5V. Alternatively, a minimum or maximum value of an applicable voltage may be set at a front end of the regulator circuit 21c.

The switching circuit 21d may connect the regulator circuit 21c and the battery 21e. The switching circuit 21d may be maintained in an on/off state under the control of the control circuit 22.

The battery 21e may be charged by receiving power from the regulator circuit 21c. In another embodiment, a charger may be further disposed between the switching circuit 21d and the battery 21e. The charger may change the voltage or current of power input in a predetermined mode (e.g., constant current (CC) mode or constant voltage (CV) mode) to charge the battery 21e. In an embodiment of the disclosure, the DC/DC converter of the regulator circuit 21c may directly charge the battery 21e, or the charger may adjust power output from the regulator circuit 21c once again to charge the battery 21e.

According to an embodiment, the electronic device 101 may include a sensing circuit, and the sensing circuit may sense a state change of power received by the electronic device 101. For example, the sensing circuit may periodically or aperiodically measure a current/voltage value received by the coil 21L through a predetermined current/voltage sensor. The electronic device 101 may calculate the amount of power received by the electronic device 101 based on the measured current/voltage. The electronic device 101 may change the matching circuit 21a based on the measured current/voltage.

According to an embodiment, the sensing circuit may sense a change in the charging environment of the electronic device 101. For example, the sensing circuit may periodically or aperiodically measure at least one of the internal temperature or external temperature of the electronic device 101 through a predetermined temperature sensor.

According to an embodiment, the communication circuit 23 may perform communication with the wireless power transmission device 200 in a predetermined method. The communication circuit 23 may perform data communication with the communication circuit 13 of the wireless power transmission device 200. The communication circuit 23 may exchange control signals with the wireless power transmission device 200 through data communication. The communication circuit 23 may operate similarly or identically to the communication circuit 13 of the wireless power transmission device 200.

The control circuit 22 may transmit charging configuration information for receiving a required amount of power to the wireless power transmission device 200 through the communication circuit 23 based on information related to the battery state of the electronic device 101. For example, when the control circuit 22 identifies the wireless power transmission device 200 capable of transmitting wireless power, the control circuit 22 may transmit the charging configuration information for receiving a required amount of power to the wireless power transmission device 200 through the communication circuit 23 based on at least one of the total battery capacity, battery remaining capacity, number of charges, battery usage, charging mode, charging method, or wireless reception frequency band of the electronic device 101.

The control circuit 22 may transmit the power amount control information for controlling the amount of power received from the wireless power transmission device 200 to the wireless power transmission device 200 through the communication circuit 23 according to a change in the amount of power charged in the electronic device 101. For example, a first communication circuit 23a may include a switch and a capacitor or resistor. The control circuit 22 may turn the switch on/off according to the binary code of data to be transmitted based on an on/off keying modulation scheme. Impedance sensed by the wireless power transmission device 200A may detect a change in the magnitude of power or a current in the power transmission circuit 11 according to on/off of the switch, and demodulate this into a binary code, to obtain data to be transmitted by the electronic device 101.

According to an embodiment, the interface 24 of the electronic device 101 may connect a TA (or external electronic device) and the electronic device 101 through a connector. The interface 24 may include a USB communication module connected to the control circuit 22 or a processor through a designated system interface, for example, an inter-integrated circuit (I2C). For example, the TA may communicate with a USB communication module of the wireless power reception device 101 through a CC terminal of a USB C type. According to an embodiment, the USB communication module may include a USB power delivery (PD) communication module for USB PD communication. According to an embodiment, the TA may be a TA supporting the programmable power supply (PPS) standard, or a general TA that does not support the PPS. For example, the TA supporting the PPS may change or adjust an output TA voltage or an output TA current in various manners under the control of the control circuit 22 of the wireless power reception device 101. The TA that does not support the PPS may have a fixed output TA voltage or output TA current. The interface 24 may be a wired interface.

In FIG. 3, the electronic device 101 according to an embodiment has been described as a device for receiving wireless power. However, the electronic device 101 may also operate as a power transmission device for transmitting wireless power to another electronic device. Further, while the wireless power transmission device 200 has been described as a device for transmitting wireless power in FIG. 3, the wireless power transmission device 200 may also operate as a power reception device for receiving wireless power from another wireless power transmission device.

FIG. 4 is a perspective view illustrating an electronic device and a case of the electronic device, which are separated from each other according to an embodiment.

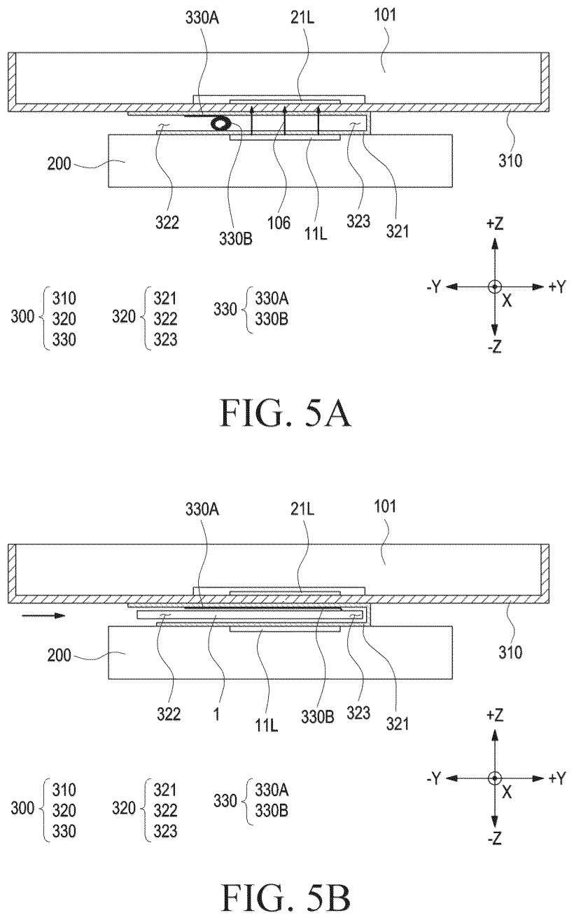

The embodiment of FIG. 4 may be combined with the embodiments of FIGS. 1 to 3 or the embodiments of FIGS. 5A to 9.

The configuration of the electronic device 101 in FIG. 4 may be partially or wholly the same as the configuration of the electronic device 101 in FIGS. 1 to 3.

According to an embodiment, a case 300 of the electronic device (hereinafter, referred to as a “case”) may be a protective case for protecting the electronic device 101. For example, the case 300 may prevent scratches on the exterior of the electronic device 101. Further, the case 300 may protect the exterior or internal electrical components of the electronic device 101 from external impact. The case 300 of the electronic device may be provided on and cover or protect the exterior of the electronic device 101.

According to an embodiment, the case 300 may include a case body 310 or a storage portion 320.

According to an embodiment, the case body 310 may have a shape that is provided adjacent to and surrounds at least a portion of the electronic device 101 mounted on the case 300. The case body 310 may include a flat portion 311 or a side portion 313.

According to an embodiment, the flat portion 311 may have a plate shape. For example, when the electronic device 101 is mounted on the case 300, the flat portion 311 may be provided on and cover the rear surface of the electronic device 101.

According to an embodiment, the side portion 313 may extend from an edge of the flat portion 311. For example, when the electronic device 101 is mounted on the case 300, the side portion 313 may be provided on and cover a side surface of the electronic device 101.

According to an embodiment, the case body 310 may further include a camera opening 312. For example, the camera opening 312 may be formed on the flat portion 311 of the case body 310. For example, the camera opening 312 may be formed as a hole penetrating through the flat portion 311. The camera opening 312 may have a shape or position corresponding to that of a rear camera module 180a (e.g., the camera module 180 of FIG. 1) of the electronic device 101.

According to an embodiment, the case body 310 may be configured to include a recess structure capable of accommodating the electronic device 101 therein, when the electronic device 101 is mounted.

According to an embodiment, the storage portion 320 may be formed on the flat portion 311 of the case body 310. For example, the flat portion 311 may include a first surface provided on and covering the rear surface of the electronic device 101 and a second surface facing in the opposite direction of the first surface. The storage portion 320 may be disposed on the second surface of the flat portion 311. According to an embodiment, the storage portion 320 may be formed integrally with the case body 310, or may be formed separate from the case body 310 and coupled (connected) or assembled to the case body 310.

According to an embodiment, the storage portion 320 may provide a storage space in which a user's card (e.g., a credit card, a transportation card, or a door lock card) may be stored. Accordingly, the user using the case 300 and the electronic device 101 may carry the electronic device 101 and the card together by storing the card in the storage portion 320 of the case 300.

According to an embodiment, the storage portion 320 has one side open, so that a card may be stored or inserted through the open portion. According to an embodiment, the storage portion 320 may be interpreted as a pocket or wallet of the case 300.

FIGS. 5A and 5B are cross-sectional views illustrating a case of an electronic device, the electronic device, and a wireless power transmission device according to an embodiment.

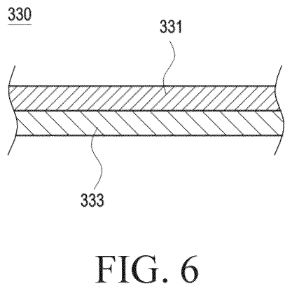

FIG. 6 is a cross-sectional view illustrating a shielding member according to an embodiment.

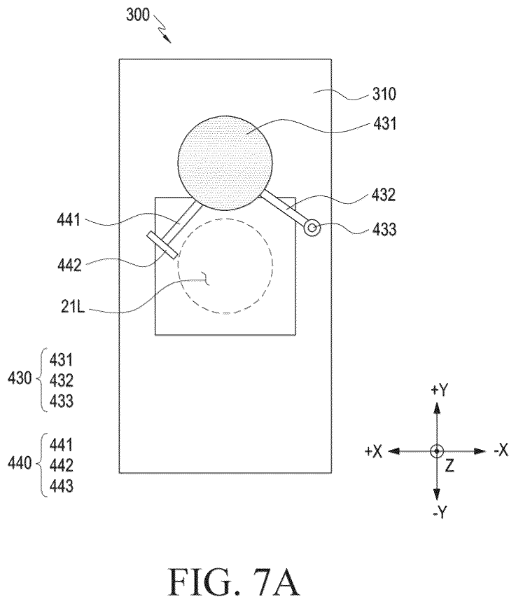

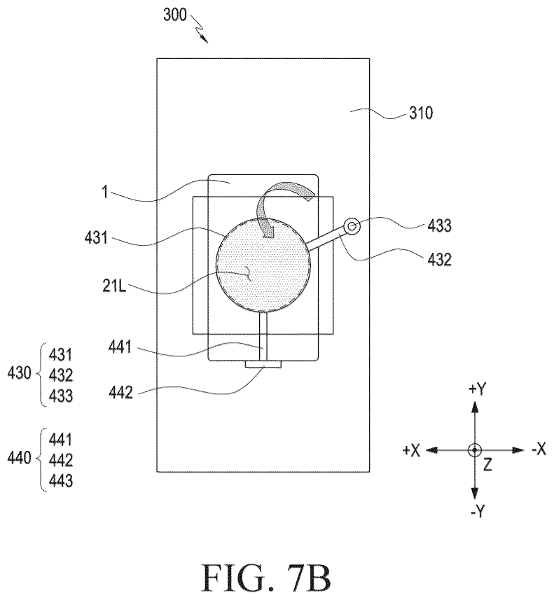

The embodiments of FIGS. 5A to 6 may be combined with the embodiments of FIGS. 1 to 4 or the embodiments of FIGS. 7A to 9.

The configuration of the electronic device 101 in FIGS. 5A to 5B may be partially or wholly the same as the configuration of the electronic device 101 in FIGS. 1 to 4. The configuration of the wireless power transmission device 200 in FIGS. 5A and 5B may be partially or wholly the same as the configuration of the wireless power transmission device 200 in FIGS. 2 and 3. The configuration of the case 300 in FIGS. 5A and 5B may be partially or wholly the same as the configuration of the case 300 in FIG. 4.

According to an embodiment, the electronic device 101 may include the coil 21L (e.g., the coil 21L of FIG. 3) for receiving the wireless power 106 in the form of electromagnetic waves. For example, the coil 21L may be referred to as a receiving coil or Rx coil.

According to an embodiment, the wireless power transmission device 200 may include the coil 11L (e.g., the coil 11L of FIG. 3) for transmitting the wireless power 106 in the form of electromagnetic waves. For example, the coil 11L may be referred to as a transmitting coil or Tx coil.

According to an embodiment, the case 300 of the electronic device may include the case body 310 (e.g., the case body 310 of FIG. 4), the storage portion 320 (e.g., the storage portion 320 of FIG. 4), or a shielding member 330.

According to an embodiment, the case body 310 may be provided on and cover at least a portion of the exterior of the electronic device 101. For example, the electronic device 101 may be mounted on the case body 310 (or the case 300).

According to an embodiment, the storage portion 320 may be formed on or coupled (connected) to the case body 310. According to an embodiment, the storage portion 320 may include a storage body 321, a card inlet 322, or a storage space 323.

According to an embodiment, the storage body 321 may be coupled (connected) to the case body 310. For example, the storage body 321 may be coupled (connected) to the flat portion (e.g., the flat portion 311 of FIG. 4) of the case body 310. The storage body 321 may have the storage space 323 formed therein for storing a card. In addition, the storage body 321 may include the card inlet 322 formed by opening one side of the storage body 321. For example, the user's card (e.g., a card 1 of FIG. 5B) may be inserted into the storage space 323 or removed from the storage space 323 through the card inlet 322.

According to an embodiment, the shielding member 330 may be disposed in the storage body 320. For example, the shielding member 330 may be disposed in the storage space 323 inside the storage body 321. According to an embodiment, at least a portion (e.g., a first region 330A) of the shielding member 330 may be disposed in a portion of the storage body 321 facing the electronic device 101 (or a portion close to the electronic device 101). For example, when a card is stored in the storage portion 320, the shielding member 330 may be located between the card and the electronic device 101. For example, when a card is stored in the storage unit 320, at least a portion of the shielding member 330 may be located between the card and the coil 21L of the electronic device 101.

According to an embodiment, the shielding member 330 may include the first region 330A fixed to the storage body 321 and a second region 330B extending from the first region 330A.

According to an embodiment, the first region 330A of the shielding member 330 may be fixed to a portion adjacent to the card inlet 322 inside the storage body 321 (in e.g., the storage space 323).

According to an embodiment, the second region 330B of the shielding member 330 may have a shape which is partially rolled up in a first state (e.g., FIG. 5A) in which a card is not stored. For example, the second region 330B of the shielding member 330 may have a shape changed to spread out in a second state (e.g., FIG. 5B) in which a card is stored.

Referring to FIG. 6, the shielding member 330 may include a shielding sheet 331 and an elastic sheet 333. For example, the shielding member 330 may be formed by stacking the shielding sheet 331 and the elastic sheet 333.

According to an embodiment, the shielding sheet 331 may block electromagnetic waves generated from the coil 11L of the wireless power transmission device 200. For example, the shielding sheet 331 may include a sheet member formed of a non-metal (e.g., polymer) material, a ferrite material, or a nano-crystal material. According to an embodiment, the shielding sheet 331 may have, but not limited to, a thickness of about 20 mm to about 60 mm (e.g., a thickness in a Z-axis direction in FIGS. 5A and 5B).

According to an embodiment, the elastic sheet 333 may be stacked on one surface of the shielding sheet 331. According to an embodiment, the elastic sheet 333 may provide an elastic restoring force so that at least a portion (e.g., the second region 330B) of the shielding member 330 may be changed from an unfolded state (e.g., FIG. 5B) to a rolled state (e.g., FIG. 5A). For example, the elastic sheet 333 may be formed of a thin metal plate, and the metal plate may have a rounded cross-sectional shape. For example, the metal plate may be formed such that its cross-section is curved in a “C” shape. The elastic sheet 333 may be formed of various materials capable of providing an elastic restoring force.

According to an embodiment, when the shielding member 330 is in the unfolded state (e.g., FIG. 5B), the shielding sheet 331 of the shielding member 330 may face the electronic device 101, and the elastic sheet 333 of the shielding member 330 may face the wireless power transmission device 200. According to an embodiment, when the shielding member 330 is in the unfolded state (e.g., FIG. 5B), the shielding sheet 331 of the shielding member 330 may face the wireless power transmission device 200, and the elastic sheet 333 of the shielding member 330 may face the electronic device 101.

According to an embodiment, the first region 330A and the second region 330B of the shielding member 330 may be formed as a stack structure of the shielding sheet 331 and the elastic sheet 333.

According to an embodiment, when the shielding member 330 is in the unfolded state, the shielding sheet 331 may be disposed between the coil 21L and the elastic sheet 333. According to an embodiment, when the shielding member 330 is in the unfolded state, the elastic sheet 333 may also be disposed between the coil 21L and the shielding sheet 331.

Referring to FIG. 5A, the electronic device 101 is shown as charged by the wireless power transmission device 200, with no card stored in the storage portion 320 (e.g., the first state).

According to an embodiment, in the first state, the second region 330B of the shielding member 330 may be disposed in a rolled shape by the elastic sheet (e.g., the elastic sheet 333 of FIG. 6). Further, in the first state, the second region 330B of the shielding member 330 may not be located between the coil 11L of the wireless power transmission device 200 and the coil 21L of the electronic device 101. For example, when viewed in a first direction (e.g., in the Z-axis direction), the second region 330B of the shielding member 330 may not overlap the coil 21L of the electronic device 101. The first direction (e.g., the Z-axis direction) may be defined as, but not limited to, a direction in which the electronic device 101 faces the wireless power transmission device 200 or a direction in which the wireless power transmission device 200 faces the electronic device 101, when the electronic device 101 is mounted on the wireless power transmission device 200.

Accordingly, the wireless power 106 in the form of electromagnetic waves transmitted from the coil 11L of the wireless power transmission device 200 may be received by the coil 21L of the electronic device 101. The electronic device 101 may charge the battery (e.g., the battery 189 of FIG. 1) with the wireless power 106 received through the coil 21L.

Referring to FIG. 5B, with a card stored in the storage portion 320 (e.g., the second state), the electronic device 101 is shown as not charged by the wireless power transmission device 200.

According to an embodiment, in the second state, the second region 330B of the shielding member 330 may be pressed and spread by the card 1. For example, in the second state, the second region 330B of the shielding member 330 may be located between the coil 11L of the wireless power transmission device 200 and the coil 21L of the electronic device 101. For example, in the second state, the second region 330B of the shielding member 330 may be located between the coil 21L of the electronic device 101 and the card 1. For example, when viewed in the first direction (e.g., the Z-axis direction), the second region 330B of the shielding member 330 may overlap the coil 21L of the electronic device 101.

According to an embodiment, in the second state, the second region 330B of the shielding member 330 may be provided on and cover the coil 21L of the electronic device 101.

According to an embodiment, in the second state, the shielding member 330 may block a signal or ping energy transmitted from the coil 11L of the wireless power transmission device 200. Accordingly, the electronic device 101 may be maintained in a charging standby mode state by preventing the transmitted signal or ping energy from reaching the coil 21L of the electronic device 101.

According to an embodiment, in the second state, since the electronic device 101 is maintained in the charging standby mode state, the coil 11L of the wireless power transmission device 200 may not transmit wireless power. Accordingly, the card 1 may not be exposed to an electromagnetic field generated from the coil 11L, and an internal circuit or internal antenna of the card 1 may be prevented from being damaged.

Further, since the card 1 is not exposed to wireless power, the internal antenna (e.g., near field communication (NFC) antenna) of the card 1 may be prevented from being heated or damaged by wireless power.

When the card 1 is removed from the storage portion 320, the elastic sheet 333 may cause the second region 330B of the shielding member 330 to change into the rolled shape again, so that when viewed in the first direction (e.g., the Z-axis direction), the shielding member 330 may be disposed not to be provided on and cover the coil 21L, as illustrated in FIG. 5A.

FIGS. 7A and 7B are plan views illustrating a shielding member of a case in an electronic device according to an embodiment.

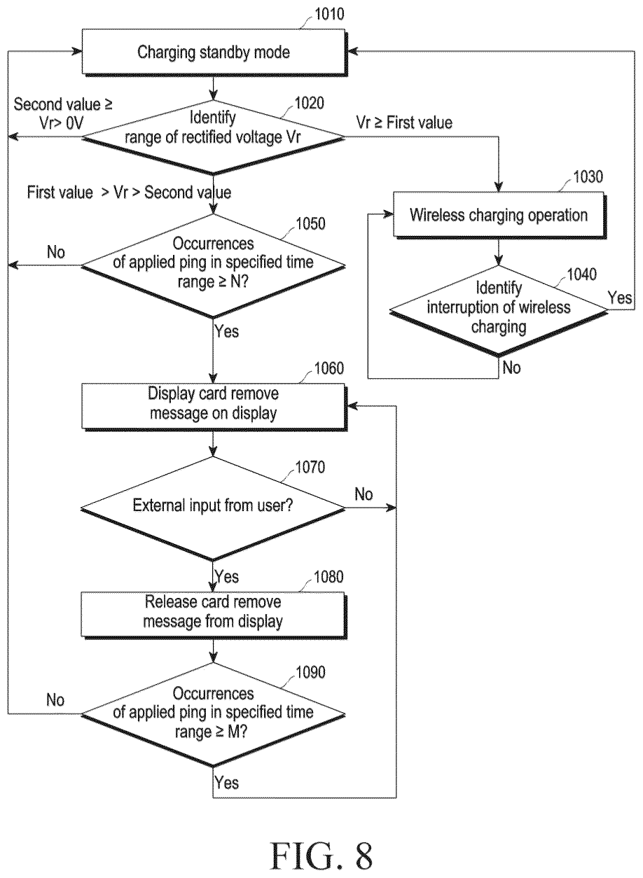

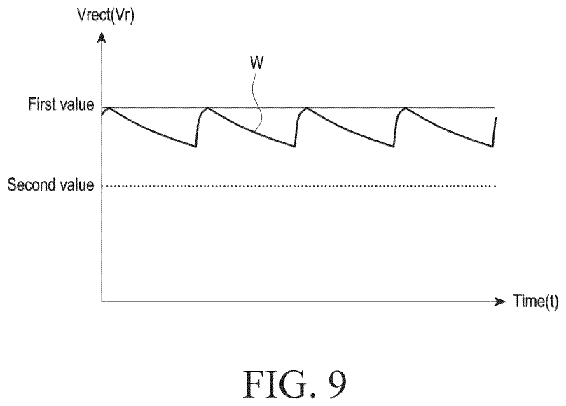

The embodiments of FIGS. 7A and 7B may be combined with the embodiments of FIGS. 1 to 6 or the embodiments of FIGS. 8 and 9.

The configuration of the case 300 in FIGS. 7A and 7B may be partially or wholly the same as the configuration of the case 300 in FIGS. 4 to 5B.

Referring to FIGS. 7A and 7B, the case 300 of the electronic device may include the case body 310 (e.g., the case body 310 of FIGS. 4 to 5B), the storage portion (e.g., the storage portion 320 of FIGS. 4 to 5B), a shielding member 430 (e.g., the shielding member 330 of FIGS. 5A and 5B), or a support member 440.

According to an embodiment, the shielding member 430 may be disposed inside the storage portion (e.g., in the storage space 323 of FIGS. 5A and 5B).

According to an embodiment, the shielding member 430 may include a shielding sheet 431, a connecting member 432, and a rotation shaft 433.

According to an embodiment, the shielding sheet 431 may block electromagnetic waves generated from a coil (e.g., the coil 11L of FIG. 3) of a wireless power transmission device (e.g., the wireless power transmission device 200 of FIGS. 2 and 3). For example, the shielding sheet 431 may include a sheet member formed of a non-metal (e.g., polymer) material, a ferrite material, or a nano-crystal material. According to an embodiment, the shielding sheet 431 may have, but not limited to, a thickness of about 20 mm to about 60 mm (e.g., a thickness in the Z-axis direction in FIGS. 7A and 7B). For example, the shielding sheet 431 may have, but not limited to, a circular shape. For example, the shielding sheet 431 may be formed in a shape similar to the coil 21L of the electronic device.

According to an embodiment, the connecting member 432 may be connected to a portion of the shielding sheet 431. For example, the connecting member 432 may have one end connected to a portion of the shielding sheet 431, and the other end connected to the rotation shaft 433.

According to an embodiment, the rotation shaft 433 may be fixed to at least a portion of the storage space (e.g., the storage space 323 of FIGS. 5A and 5B). The other end of the connecting member 432 may be rotatably connected to the rotation shaft 433. Accordingly, the connecting member 432 and the shielding sheet 431 connected to the connecting member 432 may be rotated relative to the rotation shaft 431.

According to an embodiment, the rotation shaft 433 may be rotatably coupled (connected) to at least a portion of the storage space. The other end of the connecting member 432 may be fixed to the rotation shaft 433. As the rotation shaft 433 rotates around at least a portion of the storage space, the connecting member 432 and the shielding sheet 431 connected to the connecting member 432 may rotate together.

The shielding member 430 may further include an elastic member that provides an elastic restoring force to the connecting member 432. The elastic member may press the connecting member 432 so that when no card is stored, the shielding sheet 431 does not cover the coil 21L, thereby rotating the connecting member 432 and the shielding sheet 431.

According to an embodiment, the support member 441 may include a first support portion 441 connected and/or coupled (connected) to the shielding sheet 431, and a second support portion 442 connected and/or coupled (connected) to the first support portion 441.

According to an embodiment, the first support portion 441 may extend from at least a portion of the shielding sheet 431. For example, the first support portion 441 may extend radially with respect to the center of the shielding sheet 431. Further, the first support portion 441 may have one end connected to the shielding sheet 431 and the other end connected to the second support portion 442.

According to an embodiment, the second support portion 442 may be connected to the other end of the first support portion 441. In addition, the second support portion 442 may extend substantially perpendicular to the first support portion 441.

Referring to FIG. 7A, no card is shown as stored in the storage portion (e.g., the first state).

According to an embodiment, in the first state, when viewed in the first direction (e.g., in the Z-axis direction), the shielding sheet 431 of the shielding member 430 may be disposed not to cover the coil 21L.

According to an embodiment, in the first state, when the electronic device (e.g., the electronic device 101 of FIGS. 1 to 5B) is charged by the wireless power transmission device (e.g., the wireless power transmission device 200 of FIGS. 2 and 3), the shielding sheet 431 may not be disposed between the coil (e.g., the coil 11L of FIG. 3) of the wireless power transmission device and the coil 21L of the electronic device.

Referring to FIG. 7B, the card 1 is shown as stored in the storage portion (e.g., the second state).

According to an embodiment, in the second state, the card 1 may be introduced into the storage space of the storage portion, while pressing the second support portion 442. Herein, while the second support portion 442 is pressurized, the shielding sheet 431 and the connecting member 432 of the shielding member 430 connected to the first support portion 441 may be rotated in one direction (e.g., a first rotation direction) with respect to the rotation shaft 433. Accordingly, when viewed in the first direction (e.g., the Z-axis direction), the shielding sheet 431 may be provided on and cover the coil 21L of the electronic device. For example, the shielding sheet 431 may be disposed between the coil (e.g., the coil 11L of FIG. 3) of the wireless power transmission device and the coil 21L of the electronic device. For example, the shielding sheet 431 may be disposed between the card 1 and the coil 21L of the electronic device.

According to an embodiment, in the second state, the shielding member 430 may block a signal or ping energy transmitted from the coil of the wireless power transmission device. Accordingly, since the transmitted signal or ping energy does not reach the coil 21L of the electronic device, the electronic device 101 may be maintained in the charging standby mode state.

According to an embodiment, in the second state, since the electronic device is maintained in the charging standby mode state, the coil of the wireless power transmission device may not transmit wireless power. Accordingly, the card 1 may be prevented from being exposed to wireless power, and the internal circuit or internal antenna of the card 1 may be prevented from being damaged.

Further, since the card 1 is not exposed to wireless power, the phenomenon of the internal antenna (e.g., NFC antenna) of the card 1 being heated or damaged by wireless power may be prevented.

According to an embodiment, when the card is removed from the storage portion, the elastic member may press the connecting member 432, so that the connecting member 432 and the shielding sheet 431 rotate in the other direction (e.g., a second rotation direction opposite to the first rotation direction) opposite to the one direction, and thus when viewed in the first direction (e.g., the Z-axis direction), the shielding sheet 431 may be disposed not to cover the coil 21L as illustrated in FIG. 7A.

FIG. 8 is a flowchart illustrating control of wireless charging of an electronic device according to an embodiment.

FIG. 9 is a graph illustrating a rectified voltage of a rectifier circuit in an electronic device according to an embodiment.

The embodiments of FIGS. 8 and 9 may be combined with the embodiments of FIGS. 1 to 7B.

The electronic device described with reference to FIG. 8 may be the electronic device mounted on the case 300 described as an example with reference to FIGS. 4 to 7B.

Referring to FIG. 8, the electronic device (e.g., the electronic device 101 of FIGS. 1 to 5B) may be in the standby state for wireless charging in operation 1010. For example, the electronic device may be in the wireless charging standby mode.

The processor (e.g., the processor 120 of FIG. 1 or the control circuit 22 of FIG. 3) of the electronic device may identify a voltage (hereinafter, referred to as a rectified voltage Vr) output from the rectifier circuit (e.g., the rectifier circuit 21b of FIG. 3) of the electronic device in operation 1020. For example, the processor of the electronic device may identify the range or magnitude of the rectified voltage through the sensing circuit of the electronic device.

According to an embodiment, the electronic device may be disposed adjacent to a wireless power transmission device (e.g., the wireless power transmission device 200 of FIGS. 2 and 3) or mounted on the wireless power transmission device for wireless charging.

According to an embodiment, ping energy (or a ping signal) transmitted from the coil (e.g., the coil 11L of FIG. 3) of the wireless power transmission device may be applied to the coil (e.g., the coil 21L of FIG. 3) of the electronic device.

According to an embodiment, the rectifier circuit of the electronic device may output the rectified voltage Vr to the regulator circuit (e.g., the regulator circuit 21c of FIG. 3) by the ping energy (or the ping signal).

According to an embodiment, the processor of the electronic device may identify the magnitude or range of the rectified voltage Vr.

When the magnitude or range of the rectified voltage Vr is equal to or greater than a first value, which is a set voltage value, the processor of the electronic device may charge the battery (e.g., the battery 189 of FIG. 1 or the battery 21e of FIG. 3) by operating the power reception circuit (e.g., the power reception circuit 21 of FIG. 3) in operation 1030. For example, the electronic device may be in a wireless charging state. The first value may be, but not limited to, about 2.7V, and have various voltage values depending on design changes. For example, when the magnitude or range of the rectified voltage Vr is equal to or greater than the first value, the electronic device may be in a state where it is mounted on the wireless power transmission device, with no card stored in the case of the electronic device.

According to an embodiment, the processor of the electronic device may identify the interruption of the wireless charging in operation 1040. For example, the processor of the electronic device may identify an event related to the interruption of the wireless charging of the electronic device in operation 1040. For example, the event related to the interruption of wireless charging may include occurrence of control error packet (CEP) timeout, a charging completion event, and a case where the charge level of the battery drops to or below a reference value.

According to an embodiment, when the interruption of the wireless charging is identified (e.g., when an event related to the interruption of the wireless charging occurs), the electronic device may perform operation 1010 (e.g., operating in the charging standby mode).

According to an embodiment, when the interruption of the wireless charging is not identified (e.g., when the event related to the interruption of the wireless charging does not occur), the electronic device may perform operation 1030 (e.g., the wireless charging operation).

In operation 1020, when the magnitude or range of the rectified voltage Vr identified by the processor of the electronic device is less than or equal to a second value, which is a set voltage value, the electronic device may perform operation 1010 (the wireless charging standby mode operation). The second value may be, but not limited to, about 1.0V, and have various voltage values depending on design changes. In addition, the second value may be smaller than the first value. For example, when the magnitude or range of the rectified voltage Vr is within 0V to the second value, the electronic device may be in a state where it is not mounted on the wireless power transmission device.

In operation 1020, when the magnitude or range of the rectified voltage Vr identified by the processor of the electronic device is less than the first value and greater than the second value, the processor of the electronic device may identify whether the ping energy (or the ping signal) applied to the coil of the electronic device occurs N or more times within a specified time range in operation 1050. For example, the processor of the electronic device may identify the ping energy (or the ping signal) in the waveform of the rectified voltage output from the rectifier circuit.

For example, when the ping energy (or the ping signal) applied in the specified time range occurs less than N times, the electronic device may perform operation 1010 (e.g., the wireless charging standby mode operation). When the ping energy applied in the specified time range occurs less than N times, the electronic device may be in a state where it is not mounted on the wireless power transmission device or in a state where it is disposed at an adjacent location but not mounted for charging.

For example, when the ping energy (or the ping signal) applied in the specified time range occurs N or more times, the processor of the electronic device may display a card remove message (e.g., a user interface (UI) message) on the display (e.g., the display module 160 of FIG. 1) of the electronic device in operation 1060. For example, when the ping energy (or the ping signal) applied in the specified time range occurs N or more times, the electronic device may be in a state where it is mounted on the wireless power transmission device and a card may be stored in the storage portion of the case. When the card is stored in the storage portion of the case, the shielding member (e.g., the shielding member 330 of FIGS. 5A and 5B or the shielding member 430 of FIGS. 7A and 7B) may be provided on and cover the coil (e.g., the coil 21L of FIG. 3) of the electronic device. Accordingly, the ping energy (or the ping signal) transmitted from the coil of the wireless power transmission device may be received by the coil of the electronic device, while being blocked within a predetermined range.

Accordingly, compared to the state where the shielding member does not cover the coil of the electronic device, the rectified voltage output from the rectifier circuit of the electronic device may have a relatively low value.

Referring to FIG. 9, the waveform of a rectified voltage Vrect (Vr) output from the rectifier circuit over time t is illustrated. As illustrated in FIG. 9, the waveform W of the rectified voltage Vr may be between the first value and the second value, and repeatedly form one pattern. Since the waveform W of the rectified voltage Vr has a waveform or pattern substantially similar to the ping energy applied to the coil of the electronic device, the period of the ping energy applied to the coil of the electronic device may be identified from the waveform of the rectified voltage Vr. For example, one pattern of the waveform W of the rectified voltage W may be identified as an element corresponding to one ping energy. As illustrated in FIG. 9, when the waveform W of the rectified voltage Vr is between the first value and the second value and occurs N or more times in a specified time range, the processor of the electronic device may recognize that a card is stored in the storage portion. Accordingly, the processor of the electronic device may display a message “Remove the card from the case” on the display of the electronic device in operation 1060. For example, a time for which the message is displayed on the display may be a set time or longer, for example, about 3 seconds or more.

For example, in operation 1050, when the applied ping energy occurs less than N times in the specified time range, the electronic device may perform operation 1010 (e.g., the wireless charging standby mode operation).

After the user identifies the message (or UI message) requesting card removal, the user may recognize that the card is stored in the storage portion. The message may be provided with a button through which the user may input an external input. For example, the user may input information indicating that the card has been removed from the storage portion into the electronic device by pressing an “OK” button in the card remove message.

According to an embodiment, the processor of the electronic device may identify whether an external input from the user has been input in operation 1070.

When the external input from the user has not been input, the electronic device may perform operation 1060 (e.g., displaying the card remove message again).

When the external input from the user has been input, the processor of the electronic device may release the card remove message from the display in operation 1080.

According to an embodiment, after releasing the card remove message, the processor of the electronic device may identify whether the ping energy (or the ping signal) applied to the coil of the electronic device has occurred M or more times in a specified time range in operation 1090. For example, the processor of the electronic device may identify the ping energy (or the ping signal) in the waveform of the rectified voltage output from the rectifier circuit. M may be, but not limited to, 1.

For example, when the ping energy (or the ping signal) applied in the specified time range occurs less than M times, the electronic device may perform operation 1010 (e.g., the wireless charging standby mode operation). When the ping energy (or the ping signal) applied in the specified time range occurs less than M times, the card may have been removed from the storage portion.

For example, when the ping energy (or the ping signal) applied in the specified time range occurs M or more times, the electronic device may perform operation 1060 (e.g., displaying the card remove message). When the ping energy (or the ping signal) applied in the specified time range occurs M or more times, the card may not have been removed from the storage portion. Accordingly, the processor of the electronic device may perform operation 1060 (e.g., displaying the card remove message again) to prompt the user to remove the card from the storage portion.

In order to protect the exterior of an electronic device, an accessory such as a case that covers the electronic device may be used. An accessory such as the case may provide a space for storing a card (e.g., a credit card, a transportation card, or a door lock card) to increase usability.

When the electronic device is mounted on a charging device for wireless charging, with a card stored in the case, wireless power in the form of electromagnetic waves may be introduced to an internal circuit or internal antenna of the card, thereby causing damage to the circuit or antenna, or heating up the internal antenna of the card and thus causing a fire in the card or the electronic device.

According to an embodiment, a case including a shielding member that may prevent damage to an internal circuit or internal antenna of the card when an electronic device is mounted on a wireless power transmission device for wireless charging, and the electronic device mounted thereon may be provided.

However, the problem to be solved in the disclosure is not limited to the problem mentioned above, and may be determined in various ways without departing from the spirit and scope of the disclosure.

According to an embodiment, when a card is stored in a case of an electronic device, a wireless charging operation is not performed. Accordingly, damage to the card may be prevented.

The effects obtainable in the disclosure are not limited to the effects mentioned above, and other effects not mentioned may be clearly understood by those skilled in the art from the following description.

According to an embodiment, the case 300 of the electronic device 101 may include the case body 310, the card storage portion 320, or the shielding member 330 or 430. The card storage portion 320 may be disposed on one surface of the case body. The card storage portion 320 may include the storage space 323 for storing a card therein. The shielding member 330 or 430 may be disposed in the storage space. At least a portion of the shielding member 330 or 340 may be configured to change in shape or position to be located between the card and a coil of the electronic device when the card is stored in the storage space.

According to an embodiment, the shielding member may include the shielding sheet 331 or 431. When the card is stored in the storage space, the shielding sheet 331 or 431 may be disposed to be provided on and cover the coil of the electronic device. When the card is not stored in the storage space, the shielding sheet 331 or 431 may be disposed not to cover the coil of the electronic device.

According to an embodiment, the shielding sheet may include at least one of a non-metal material, a ferrite material, or a nano-crystal material.

According to an embodiment, the shielding sheet may be configured to block wireless power transmitted from the external wireless power transmission device 200 from reaching the coil of the electronic device.

According to an embodiment, the shielding member may include the first region 330A or the second region 330B. The first region 330A may be fixed to at least a portion of the storage space. The second region 330B may extend from the first region. The second region 330 may be disposed to be provided on and cover the coil of the electronic device or not to cover the coil of the electronic device.

According to an embodiment, the second region may be disposed to be provided on and cover the coil of the electronic device in a shape spread out from the first region or disposed not to cover the coil of the electronic device in a shape rolled toward the first region.

According to an embodiment, the shielding member 330 may include the shielding sheet 331 or the elastic sheet 333. The elastic sheet 333 may be stacked on the shielding sheet. When the card is not stored in the storage space, the elastic sheet may be configured to provide an elastic restoring force to change the second region into a rolled shape.

According to an embodiment, the shielding member 430 may include the shielding sheet 431, the rotation shaft 433, or the connecting member 432. The rotation shaft 433 may be fixed to at least a portion of the storage space. One end of the connecting member 432 may be connected to the rotation shaft. Another end of the connecting member 432 may be connected to the shielding sheet.

According to an embodiment, when the card is stored in the storage space, the shielding sheet may be configured to rotate in one direction relative to the rotation shaft to be disposed to be provided on and cover the coil of the electronic device. When the card is not stored in the storage space, the shielding sheet may be configured to rotate in another direction relative to the rotation shaft to be disposed not to cover the coil of the electronic device.

According to an embodiment, the case may further include the support member 440. The support member 440 may be configured to support the card when the card is stored in the storage space.

According to an embodiment, the case 300 of the electronic device 101 may include the case body 310, the card storage portion 320, or the shielding member 330 or 430. The case body 310 may be configured to mount the electronic device thereon. The case body 310 may include the flat portion 311 or the side portion 313. The side portion 313 may extend from an edge of the flat portion. The card storage portion 320 may be disposed on the flat portion of the case body. The card storage portion 320 may include the storage space 323 for storing a card therein. The shielding member 330 or 430 may be disposed in the storage space. At least a portion of the shielding member 330 or 430 may be configured to be change in shape or position to be located between the card and the coil of the electronic device when the card is stored in the storage space.

According to an embodiment, the case body may further include the camera opening 312. The camera opening 312 may be formed on at least a portion of the flat portion.

According to an embodiment, the shielding member may be configured to block wireless power transmitted from an external device from reaching a coil of the electronic device, when the at least portion thereof is disposed between the card and the coil of the electronic device.

According to an embodiment, the shielding member 330 may include the shielding sheet 331 or the elastic sheet 333. The elastic sheet 333 may be stacked on the shielding sheet. The elastic sheet may be configured to provide an elastic restoring force to change the shielding sheet and the elastic sheet into a rolled shape when the card is not stored in the storage space.

According to an embodiment, the shielding member 430 may include the shielding sheet 431, the rotation shaft 433, or the connecting member 432. The rotation shaft 433 may be fixed to at least a portion of the storage space. One end of the connecting member 432 may be connected to the rotation shaft. Another end of the connecting member 432 may be connected to the shielding sheet.

According to an embodiment, the electronic device 101 may include the coil 21L, the rectifier circuit 21b, or the processor 120. The coil 21L may be configured to receive wireless power transmitted from the external wireless power transmission device 201. The rectifier circuit 21b may be configured to rectify the wireless power received through the coil. The processor 120 may be operatively connected to the coil and the rectifier circuit. The processor may be configured to identify a rectified voltage output from the rectifier circuit. Based on a first value and a second value smaller than the first value, the processor may control the electronic device to operate in a wireless charging mode, when the rectified voltage is equal to or greater than the first value. The processor may control the electronic device to operate in a charging standby mode, when the rectified voltage is equal to or less than the second value. The processor may control the display of the electronic device to display a UI message, when the rectified voltage is less than the first value and greater than the second value.

According to an embodiment, the processor may be configured to identify whether ping energy transmitted from the wireless power transmission device and applied to the coil occurs N or more times in a specified time range, when the rectified voltage is less than the first value and greater than the second value.

According to an embodiment, the processor may be configured to control the display to transmit the UI message, when the ping energy occurs N or more times in the specified time range, and to control the electronic device to operate in a charging standby mode, when the ping energy occurs less than N times in the specified time range.

According to an embodiment, the processor may be configured to identify whether an external input from a user for the UI message is received.

According to an embodiment, the processor may be configured to identify a rectified voltage output from the rectifier circuit, when the external input from the user for the UI message is received. The processor may be configured to identify whether the ping energy transmitted from the wireless power transmission device and applied to the coil occurs M or more times in a specified time range, when the rectified voltage is less than the first value and greater than the second value.

While embodiments have been described with reference to the figures, it will be understood by those of ordinary skill in the art that various changes in form and details may be made therein without departing from the spirit and scope as defined by the following claims and their equivalents.

What is claimed is:

1. A case of an electronic device comprising:
a case body;
a card storage on a surface of the case body, the card storage comprising a storage space configured to store a card; and
a shielding member in the storage space,
wherein at least a portion of the shielding member is configured to change in shape or position to be between the card and a coil of the electronic device based on the card being stored in the storage space.

2. The case of claim 1, wherein the shielding member comprises a shielding sheet configured to be on the coil of the electronic device based on the card being stored in the storage space, and configured not to be on the coil of the electronic device based on the card not being stored in the storage space.

3. The case of claim 2, wherein the shielding sheet comprises at least one of a non-metal material, a ferrite material, and a nano-crystal material.

4. The case of claim 2, wherein the shielding sheet is configured to block wireless power transmitted from an external wireless power transmission device from reaching the coil of the electronic device.

5. The case of claim 1, wherein the shielding member comprises:
a first region on at least a portion of the storage space; and
a second region extending from the first region and configured to be on the coil of the electronic device or not to be on the coil of the electronic device.

6. The case of claim 5, wherein the second region is configured to be on the coil of the electronic device in a spread out shape from the first region or configured not to be on the coil of the electronic device in a rolled shape toward the first region.

7. The case of claim 6, wherein the shielding member comprises:
a shielding sheet; and
an elastic sheet stacked on the shielding sheet,
wherein the elastic sheet is configured to provide an elastic restoring force to change the second region into the rolled shape based on the card not being stored in the storage space.

8. The case of claim 1, wherein the shielding member comprises:
a shielding sheet;
a rotation shaft on at least a portion of the storage space; and
a connecting member,
wherein a first end of the connecting member is connected to the rotation shaft and a second end of the connecting member is connected to the shielding sheet.

9. The case of claim 8, wherein the shielding sheet is configured to rotate in a first direction relative to the rotation shaft to be on the coil of the electronic device based on the card being stored in the storage space, and configured to rotate in a second direction relative to the rotation shaft to not be on the coil of the electronic device based on the card not being stored in the storage space.

10. The case of claim 1, further comprising a support member configured to support the card based on the card being stored in the storage space.

11. A case of an electronic device comprising:
a case body configured to mount the electronic device thereon, the case body comprising a flat portion and a side portion extending from an edge of the flat portion;
a card storage on the flat portion of the case body, the card storage comprising a storage space configured to store a card; and
a shielding member in the storage space,
wherein at least a portion of the shielding member is configured to change in shape or position to be between the card and a coil of the electronic device based on the card being stored in the storage space.

12. The case of claim 11, wherein the case body further comprises a camera opening on at least a portion of the flat portion.

13. The case of claim 11, wherein the shielding member is configured to block wireless power transmitted from an external device from reaching the coil of the electronic device, based on the at least portion of the shielding member being between the card and the coil of the electronic device.

14. The case of claim 11, wherein the shielding member comprises:
a shielding sheet; and
an elastic sheet on the shielding sheet, and
wherein the elastic sheet is configured to provide an elastic restoring force to change the shielding sheet and the elastic sheet into a rolled shape based on the card not being stored in the storage space.

15. The case of claim 11, the shielding member comprises:
a shielding sheet;
a rotation shaft on at least a portion of the storage space; and
a connecting member,
wherein a first end of the connecting member is connected to the rotation shaft and a second end of the connecting member is connected to the shielding sheet.

16. The case of claim 11, wherein the shielding member comprises a shielding sheet configured to be on the coil of the electronic device based on the card being stored in the storage space, and configured not to be on the coil of the electronic device based on the card not being stored in the storage space.

17. The case of claim 11, wherein the shielding sheet comprises at least one of a non-metal material, a ferrite material, and a nano-crystal material.

18. The case of claim 11, wherein the shielding member comprises:
a first region on at least a portion of the storage space; and
a second region extending from the first region and configured to be on the coil of the electronic device or not to be on the coil of the electronic device.

19. The case of claim 18, wherein the second region is configured to be on the coil of the electronic device in a spread out shape from the first region or configured not to be on the coil of the electronic device in a rolled shape toward the first region.

20. The case of claim 11, further comprising a support member configured to support the card based on the card being stored in the storage space.
